(19) United States
(12) Patent Application Publication
(10) Pub. No.: US 2009/0035902 A1
(43) Pub. Date: Feb. 5, 2009

(54) INTEGRATED METHOD OF FABRICATING A MEMORY DEVICE WITH REDUCED PITCH

(75) Inventors: Jeff J. Xu, Jhubei City (TW); Anthony Yen, Hsinchu (TW); Chia-Ta Hsieh, Tainan (TW); Chia-Chi Chung, Hsinchu (TW); Cheng-Ming Lin, Hsin-Chu (TW)

Correspondence Address: HAYNES AND BOONE, LLP;IP Section, 2323 Victory Avenue, Suite 700, Dallas, TX, 75219, US

(73) Assignee: TAIWAN SEMICONDUCTOR MANUFACTURING COMPANY, LTD., Hsin-Chu (TW)

(21) Appl. No.: 11/831,031

(22) Filed: Jul. 31, 2007

(51) Int. Cl. H01L 21/336

(52) U.S. Cl. 438/259; 257/E21.409

(57) ABSTRACT

Provided is a method of fabricating a memory device. A substrate including an array region and a peripheral region is provided. A first feature and a second feature are formed in the array region. The first feature and the second feature have a first pitch. A plurality of spacers abutting each of the first feature and the second feature are formed. The plurality of spacers have a second pitch. A third feature in the peripheral region and a fourth and fifth feature in the array region are formed concurrently. The forth and fifth feature have the second pitch.

### BACKGROUND

The present disclosure relates generally to semiconductor manufacturing and, more particularly, to a method of fabricating a memory device having features in an array and peripheral region.

As technologies progress, semiconductor devices are characterized by decreasing dimension requirements over previous generation devices. However, such a decrease in dimensions is limited by the photolithography tools used in the fabrication of the devices. The minimum size of features and spaces fabricated by a photolithography tool is dependent upon the tool's resolution capabilities. Though tools have been produced to increase the resolution capabilities, such as immersion lithography tools, the increases are often not sufficient and the time to market for such tools is often slower than the development cycle for the next generation devices. Alternative methods may exist to provide for a decreased minimum pitch (e.g. sum of the feature size and the width of a space between features); however, they are often inefficient for example, adding costs and time to device fabrication.

Memory devices, including, for example, flash memory, include a memory array region and a peripheral region. The array region includes memory elements (e.g. cells) for storing information such as, “0” or “1.” The peripheral region includes logic circuitry for interfacing with the memory elements. The array may require a pitch dimension, and such a pitch dimension may be quite restrictive. For example, NAND/NOR flash technology may need a minimum pitch of 80 or 60 nm (e.g. a feature (or line)/space dimension of 40/40 nm or 30/30 nm which is the width of a feature and the width of the spacing between features). However, conventional methods of providing such a restrictive pitch include disadvantages such as, unavailability of capable lithography equipment, inability to fabricate an array and a peripheral region concurrently, and/or other disadvantages.

As such, an improved method of fabricating semiconductor device is needed.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flow-chart illustrating an embodiment of a method of forming a semiconductor device.

FIG. 2 is a flow-chart illustrating an embodiment of the method of FIG. 1.

FIGS. 3a, 4a, 5a, 6a, 7a, 8a, 9a, 10a, 11a, 12a, and 13a are cross-sectional views illustrating an embodiment of the method of FIG. 2.

FIGS. 3b, 4b, 5b, 6b, 7b, 8b, 9b, 10b, 11b, 12b, and 13b are top-views illustrating an embodiment of the method of FIG. 2, and correspond to the cross-sectional views of FIGS. 3a, 4a, 5a, 6a, 7a, 8a, 9a, 10a, 11a, 12a, and 13a.

### DETAILED DESCRIPTION

The present disclosure relates generally to semiconductor devices and more particularly, to a method of fabricating a memory device having features in an array and peripheral region. It is understood, however, that specific embodiments are provided as examples to teach the broader inventive concept, and one of ordinary skill in the art can easily apply the teaching of the present disclosure to other methods or devices. In addition, it is understood that the methods and apparatus discussed in the present disclosure include some conventional structures and/or processes. Since these structures and processes are well known in the art, they will only be discussed in a general level of detail. Furthermore, reference numbers are repeated throughout the drawings for sake of convenience and example, and such repetition does not indicate any required combination of features or steps throughout the drawings. Moreover, the formation of a first feature over, on, adjacent, abutting, or coupled to a second feature in the description that follows may include embodiments in which the first and second features are formed in direct contact, and may also include embodiments in which additional features may be formed interposing the first and second features, such that the first and second features may not be in direct contact. Also, the formation of a feature on a substrate, including for example, etching a substrate, may include embodiments where features are formed above the surface of the substrate, directly on the surface of the substrate, and/or extending below the surface of the substrate (such as, trenches). A substrate may include a semiconductor wafer and one or more layers formed on the wafer.

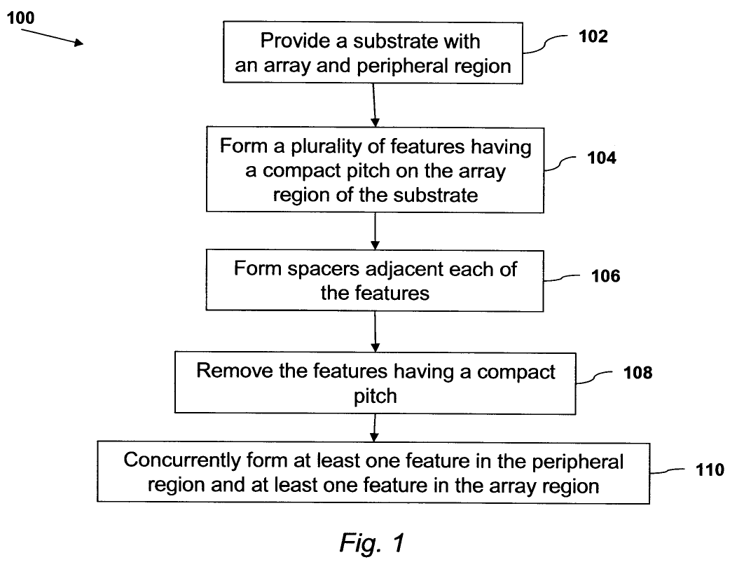

Referring to FIG. 1, illustrated is a method 100 that provides for reducing the masking pitch of a photolithography process for a memory device. The method 100 may be useful for fabrication of memory devices including restrictive (e.g. tight) design rules such as, small pitch requirements. In an embodiment, the memory device is a NAND flash device. In other embodiments, the memory device may include other flash devices including NOR flash, magnetic RAM, phase-change memory, and/or other memory devices known in the art.

The method 100 begins at step 102 where a substrate, such as a semiconductor wafer, is provided. The substrate includes an array region and a peripheral region. The substrate may include silicon in a crystalline structure. In alternative embodiments, the substrate may include other elementary semiconductors such as germanium, or may include a compound semiconductor such as, silicon carbide, gallium arsenide, indium arsenide, or indium phosphide. The substrate may include a silicon on insulator (SOI) substrate. The substrate may further comprise one or more layers formed on the substrate. Examples of layers that may be formed include insulative layers, epitaxial layers, anti-reflective coatings, conductive layers including polysilicon layers, dielectric layers, and/or other layers known in the art including as described in the embodiments below. The peripheral region may include the logic circuitry operable to interface with memory elements (e.g. memory cells) formed in the array region. The peripheral region includes at least one MOS transistor.

The method 100 proceeds to step 104 where a plurality of features are formed on the array region of the substrate. The plurality of features has a pitch. A pitch, for purposes of this disclosure, includes the width of one feature plus the width of one space to the following feature. This metric may also be expressed as line/space (e.g. 30/30, 40/40) where “line” includes the width of any feature (e.g. a line, a contact, a gate, a via, a trench), and space includes the width of one space. For purposes of distinguishing from later process steps, the pitch formed in step 104 is designated herein as a relaxed pitch. In an embodiment, the relaxed pitch is the minimum pitch for a given photolithography tool used in the method 100. In an embodiment, the photolithography tool includes a dry scanner lithography tool such as, an ASML 1400 tool known in the art. The plurality of features include at least two substantially vertical sidewalls.

The method 100 then proceeds to step 106 where a plurality of features are formed abutting the sidewalls of the features formed in step 104. The features are described herein as spacers. The features may be formed using conventional spacer formation processes. For example, a layer of material, such as oxide, may be deposited over the features formed in step 104 and etched, using an anisotropic etch, to form spacers abutting the sidewalls of the features.

The method 100 then proceeds to step 108 where the features having a relaxed pitch (and having been formed in step 104 described above) are removed. In an embodiment, the features may be removed by a wet etch process. The spacers formed in step 106 remain on the substrate. These spacers have a pitch that is less than that of the features formed in step 104. For purposes of distinguishing from other process steps, this pitch is designated herein as a “compact pitch.” In an embodiment, the compact pitch may be less than the resolution capability of a photolithography tool used in the method 100. In an embodiment, the compact pitch is half of the relaxed pitch formed in step 104.

The method 100 then proceeds to step 110 where a feature is formed in the peripheral region and a plurality of features are formed in the array region concurrently. Examples of forming features “concurrently” include forming the features simultaneously, forming the features in the same chamber of a processing tool without removing the substrate, forming the features in the same process step, and/or forming the features using the same recipe. A feature may include a pattern formed such as by etching a layer of material. A feature may also include device features such as, a trench including a shallow trench isolation (STI) structure, a line including an interconnect (e.g. metal line, contact via), a gate structure including a gate dielectric layer or gate electrode layer, a contact including a via, and/or other memory features known in the art. In forming the plurality of features in the array region, spacers formed in step 106 having a compact pitch may be used as masking elements. As such, the features formed in step 110 in the array region of the substrate may be formed having a compact pitch. In an embodiment, the compact pitch produced may be 80 nm, such that the line/space is 40 nm/40 nm. In another embodiment, the compact pitch produced may be 60 nm, such that the line/space is 30 nm/30 nm.

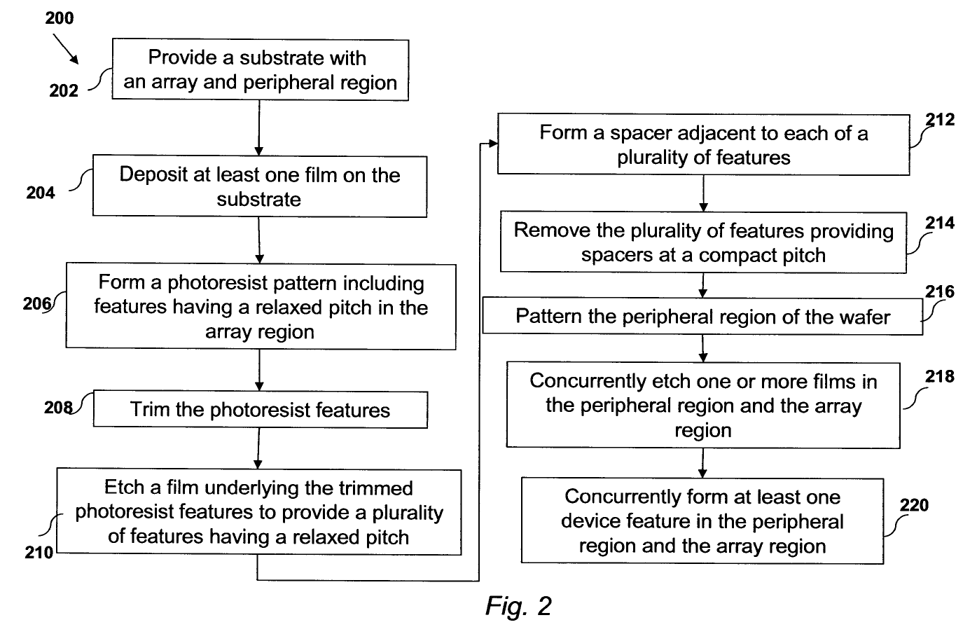

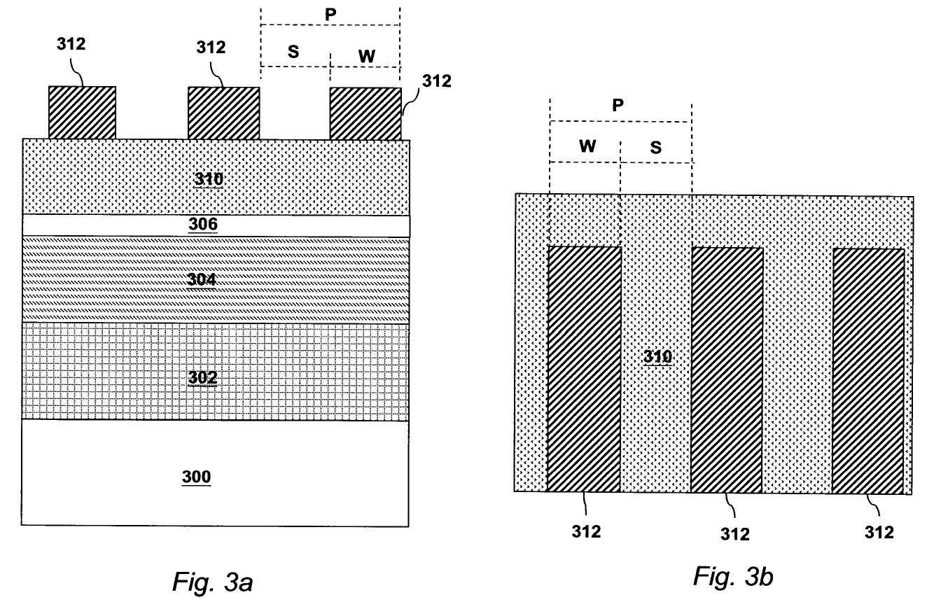

Referring now to FIG. 2, illustrated is a method 200, which is an embodiment of the method 100, described above with reference to FIG. 1. FIGS. 3a-13b include cross-sectional and top views of incremental modifications of a substrate 300 that correspond to the steps of the method 200. The method 200 and illustrated modifications of the substrate 300 include the concurrent formation of features, such as is described above with reference to step 110 of the method 100, including shallow trench isolation structures. However, one skilled in the art will recognize the method 200 may be adapted to form other features concurrently in the array and peripheral regions such as, a gate structure, a trench, a via, a line, and/or a pattern such as is produced by etching a film.

The method 200 begins at step 202 where a substrate is provided. The substrate may include silicon in a crystalline structure. In alternative embodiments, the substrate may include other elementary semiconductors such as germanium, or include a compound semiconductor such as, silicon carbide, gallium arsenide, indium arsenide, or indium phosphide. The substrate may include a silicon on insulator (SOI) substrate. The substrate includes an array region and a peripheral region. The array region includes the portion of the substrate where memory elements (e.g. cells) are formed. The peripheral region includes the portion of the substrate where a peripheral circuit (e.g. logic circuit) operably coupled to the memory elements is formed. Referring to the example of FIG. 3a, the substrate 300 is provided. In the illustrated embodiment, the substrate 300 includes silicon.

The method 200 proceeds to step 204 where at least one film is deposited on the substrate. The films may include, for example, a dielectric layer, a conducting layer, an anti-reflective coating, a hard mask layer, an insulating layer, and/or other layers known in the art. The layers may include materials having etch selectivity to one another. Referring again to the example of FIG. 3a, a silicon nitride (Si₃N₄) layer 302, a hard mask layer 304, a silicon oxy-nitride (SiON) layer 306, and a nitride layer 310 (e.g. Si₃N₄ or other nitride) are formed on the substrate 300. The hard mask layer 304 may include an amorphous carbon material. In other embodiments, the hard mask layer 304 may include silicon nitride, silicon oxy-nitride, silicon carbide, and/or other suitable dielectric materials. The composition of the layers 302, 304, 306, and 310 are exemplary only and may be varied. For example, the SiON layer 306 may include in other embodiments, an amorphous polysilicon layer. The SiON layer 306 includes a material operable to act as an anti-reflective coating (ARC). In an embodiment, the compositions are varied using materials known in the art and maintaining the etch selectivities described in the process steps below. In further embodiments, additional and/or few layers may be present on the substrate 300. The layers 302, 304, 306, and/or 310 may be formed using conventional processes known in the art such as, chemical vapor deposition (CVD), oxidation, physical vapor deposition (PVD), plasma enhanced CVD (PECVD), atmospheric pressure CVD (APCVD), atomic layer deposition (ALD), low pressure CVD (LPCVD), high density plasma CVD (HDPCVD), atomic layer CVD (ALCVD), and/or other processes known in the art.

The method 200 then proceeds to step 206 where a photoresist pattern is formed on the substrate. The photoresist pattern includes a plurality of features having a relaxed pitch. The photoresist pattern and relaxed pitch may be substantially similar to the features and relaxed pitch, described above with reference to step 104 of FIG. 1. The features of the photoresist pattern include substantially vertical sidewalls. The photoresist features may be formed by conventional methods known in the art. In an embodiment, a layer of photoresist is spun-on the substrate 300. The photoresist layer is then patterned by exposure, post exposure bake, developing, and/or other photolithography processes known in the art. Referring to the example FIGS. 3a and 3b, a plurality of photoresist features 312 are formed on the substrate 300. Illustrated in FIGS. 3a and 3b is an array region of the substrate 300. FIG. 3b includes a top view of the cross-section of FIG. 3a. The photoresist features 312 are formed at a pitch P. The pitch P is a relaxed pitch as described above. The photoresist features 312 include a width W. The photoresist features 312 have a spacing S. The pitch P includes the sum of the width W and the space S. In an embodiment, the width W is equal to the space S.

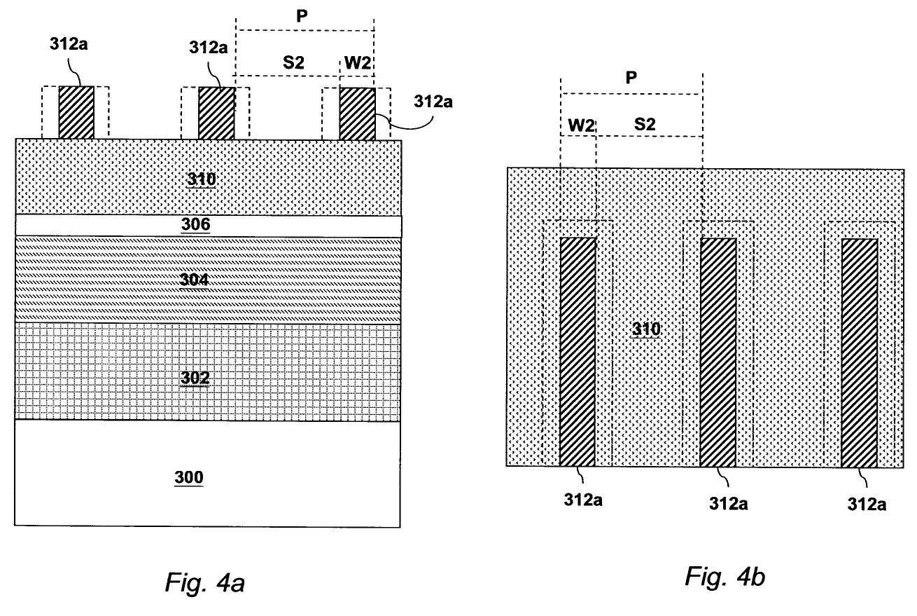

The method 200 then proceeds to step 208 where the photoresist features formed in step 206 are trimmed. The trimming may be accomplished by isotropic etching of the photoresist features. The photoresist features may be trimmed using a silicon etcher tool, e.g. plasma etcher designed for silicon etching processes. In an embodiment, the step 208 is omitted from the method 200. Referring to the example of FIGS. 4a and 4b, the trimmed photoresist features 312a are illustrated. Illustrated in FIGS. 4a and 4b is an array region of the substrate 300. FIG. 4b includes a top view of the cross-section of FIG. 4a. The trimmed photoresist features 312a include a width W2. The width W2 is less than the width W, also described above with reference to FIGS. 3a and 3b. (Note that the dashed lines illustrate the width of the spacer prior to the trim process). The spacing between photoresist features 312a is S2. The pitch is approximately the pitch P, designated a relaxed pitch. In an embodiment, the trimming process may be omitted. In the embodiment, the photoresist features 312a may be formed by a photolithography process allowing for the formation of features having a width W2.

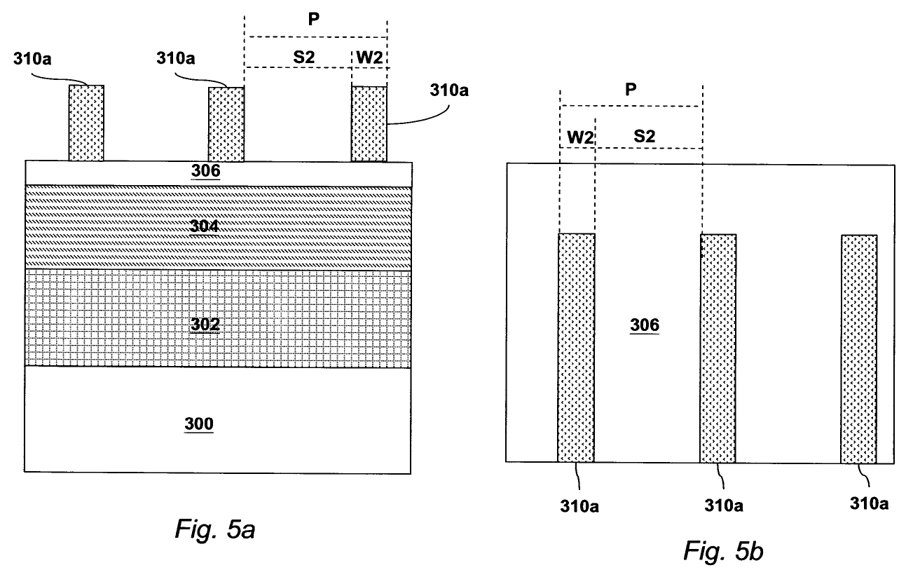

The method 200 then proceeds to step 210 where a film underlying the photoresist features, such as an insulating layer, herein designated a “first layer”, is etched. The first layer is etched using the photoresist features as masking elements. Using the photoresist features as masking elements allows the etching of the first film to form features having a relaxed pitch. The features formed of the first film also include substantially vertical sidewalls. In an embodiment, the first film is nitride (e.g. Si₃N₄). The first film may be etched in a silicon etcher, e.g. a plasma etcher designed for etching silicon. The first film may have an etch selectivity of greater than approximately 5 to 1 to the film directly underlying the first film. After the formation of the features, the photoresist is removed (e.g. stripped) from the substrate. Referring to the example of FIGS. 5a and 5b, the features 310a are formed. Illustrated in FIGS. 5a and 5b is an array region of the substrate 300. FIG. 5b includes a top view of the cross-section of FIG. 5a. The features 310a comprise nitride, being formed from the nitride layer 310 described above with reference to FIG. 3a. As the features 310a are formed using the photoresist features 312a, described above with reference to FIGS. 4a and 4b, as masking elements, the features 310a have a substantially similar width W2 as the photoresist features and substantially similar space S2, providing substantially similar pitch P. The features 310a are formed overlying the SiON layer 306. The nitride of the features 310a may have an etch selectivity to SiON, including in the SiON layer 306, of greater than approximately 5 to 1. The photoresist, including photoresist features 312a, is stripped from the substrate 300.

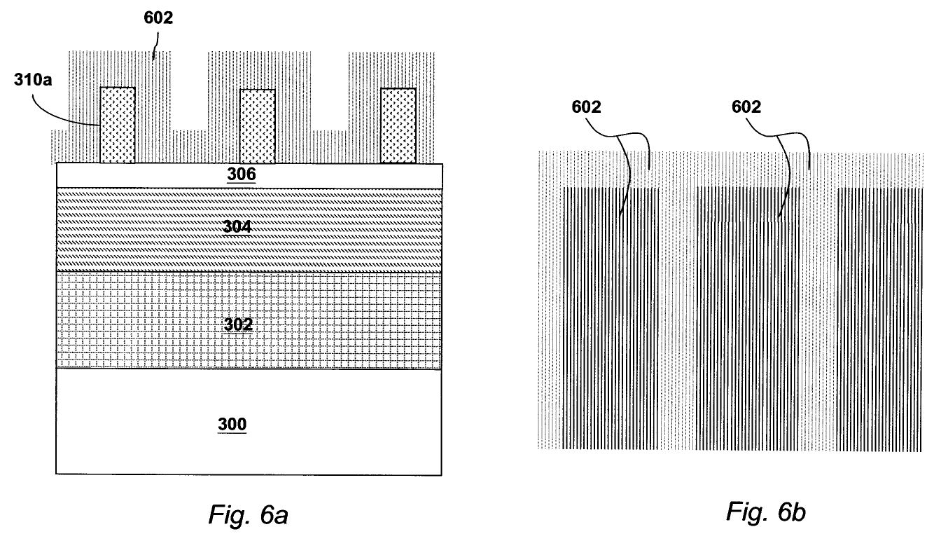

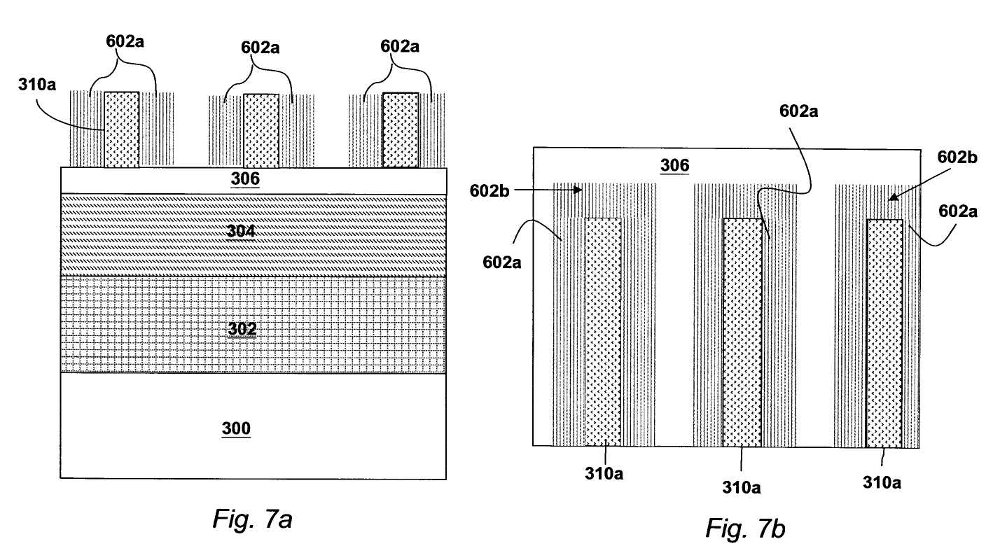

The method 200 then proceeds to step 212 where a plurality of features, e.g. spacers, are formed adjacent the plurality of features formed including the first film. The features formed may be substantially similar to the spacers formed above with reference to step 106 of FIG. 1. The spacers may be formed using conventional processes known in the art such as, depositing spacer material and etching the material to form spacers abutting the sidewalls of the features. In an embodiment, a layer of oxide (e.g. silicon dioxide) is deposited in an atomic layer deposition (ALD) chamber. The oxide layer is then etched in a dielectric etcher, e.g. plasma etcher designed for etching dielectric films such as silicon oxide. In other embodiments, the spacer may include silicon nitride, silicon carbide, silicon oxy-nitride, and/or combinations thereof. In the embodiments, a layer of spacer material may be formed by conventional processes known in the art such as, chemical vapor deposition (CVD), plasma-enhanced chemical vapor deposition (PECVD), atmospheric pressure chemical vapor deposition (APCVD), low-pressure CVD (LPCVD), high density plasma CVD (HDPCVD), atomic layer CVD (ALCVD), ALD, and/or other processes known in the art. The formed layer of spacer material may then be etched using dry etch processes known in the art. The etch selectivity of the spacer material to the directly underlying layer may be greater than approximately 5 to 1. Referring to the example of FIGS. 6a and 6b, a layer of spacer material 602 is formed on the substrate 300 and in particular overlying the features 310a. Illustrated in FIGS. 6a and 6b is an array region of the substrate 300. FIG. 6b includes a top view of the cross-section of FIG. 6a. In an embodiment, the spacer material 602 is an oxide (e.g. silicon oxide). Now referring to the example of FIGS. 7a and 7b, the spacer material layer 602, described in FIGS. 6a and 6b, is etched to form spacers 602a. Illustrated in FIGS. 7a and 7b is an array region of the substrate 300. FIG. 7b includes a top view of the cross-section of FIG. 7a. The spacers 602a abut (e.g. are adjacent to) the sidewalls of the features 310a. The spacers 602a are formed including a “cap,” referenced as 602b, shown in FIG. 7b.

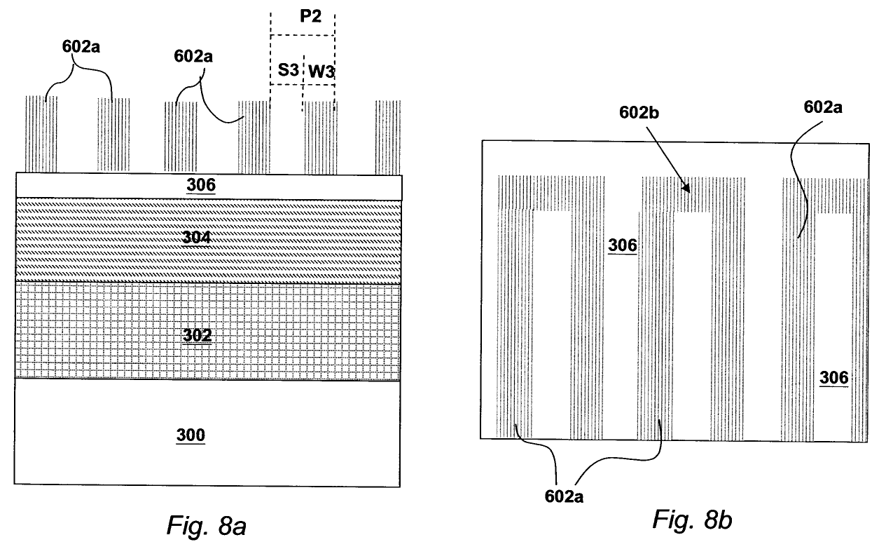

The method 200 proceeds to step 214 where the plurality of features having a relaxed pitch, formed above with reference to step 210, are removed from the substrate. The removal may be substantially similar to the step 108 described above with reference to FIG. 1. In an embodiment, the features are removed using a wet etch process. The wet etch may include a phosphoric acid etch. The removed features may have an etch selectivity to the underlying layer that is greater than 10 to 1. In an embodiment, such an etch selectivity is achieved as the underlying layer includes SiON and the removed features include Si₃N₄. The spacers formed above with reference to step 212 remain on the substrate. The spacers have a compact pitch. The compact pitch is less than the relaxed pitch of the removed features. In an embodiment, the compact pitch is half of the relaxed pitch. Thus, created is a plurality of features, termed spacers, at a compact pitch. Referring to the example of FIGS. 8a and 8b, the features 310a (described above with reference to FIGS. 7a and 7b) are removed and the spacers 602a remain on the substrate 300. Illustrated in FIGS. 8a and 8b is an array region of the substrate 300. FIG. 8b includes a top view of the cross-section of FIG. 8a. The spacers 602a include a feature width W3 and a width of a space S3. In an embodiment, W3 is substantially equal to S3. The spacers 602a also include a pitch P2, e.g. the summation of the space S3 and the feature width W3. The pitch P3 may be referenced as a compact pitch. The pitch P2 is less than the pitch P (a relaxed pitch), described above with reference to FIGS. 5a and 5b. In an embodiment, the pitch P2 is less than the resolution of a photolithography tool used in the method 200. In an embodiment, the pitch P2 may be approximately 60 nm. In an alternative embodiment, the pitch P2 may be approximately 80 nm.

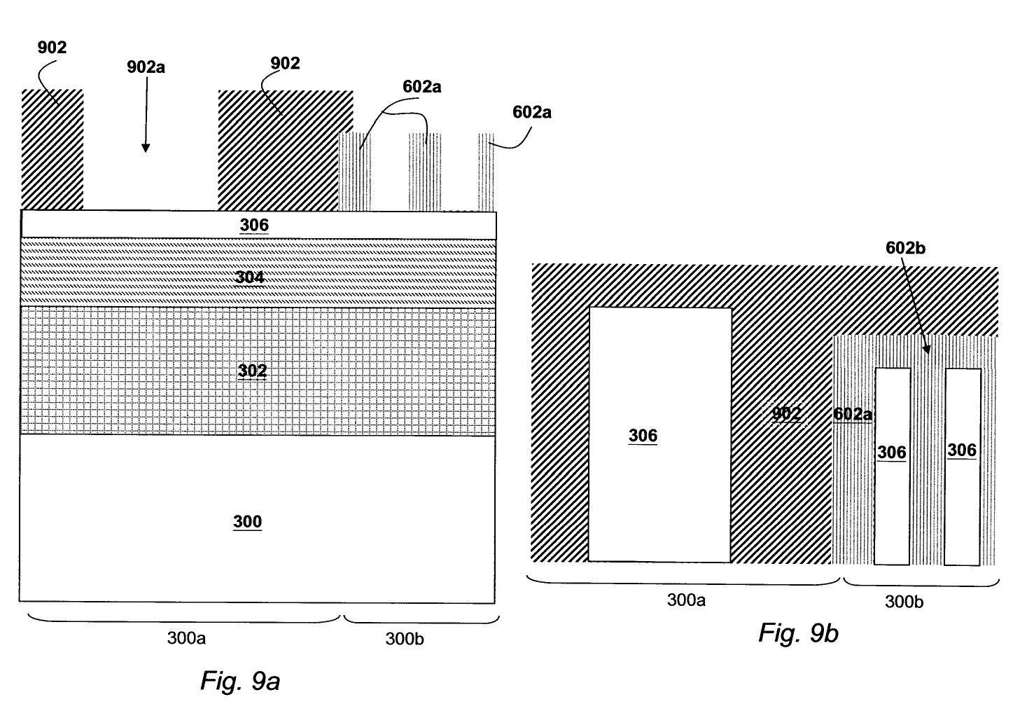

The method 200 proceeds to step 216 where the peripheral region of the substrate is patterned. The peripheral region may be patterned by photolithography processes known in the art. In an embodiment, photoresist is spun-on, exposed, based, and developed to form a pattern in the peripheral region. In an embodiment, the array region is not covered by photoresist where features have been formed. The pattern may be such that it forms a feature of the logic circuit, or a part thereof. The patterning of the peripheral area may be done without the deposition of a bottom anti-reflective coating (BARC). The film underlying the spacers (formed above with reference to step 214) may be used as an anti-reflective coating (ARC). In an embodiment, the film underlying the spacers, and underlying the photoresist on the peripheral region, includes SiON. SiON may be used as an ARC layer. Referring to the example of FIGS. 9a and 9b, a photoresist pattern 902 is formed on a peripheral region 300a of the substrate 300. Illustrated in FIGS. 9a and 9b is an array region 300b and the peripheral region 300a of the substrate 300. FIG. 9b includes a top view of the cross-section of FIG. 9a. The photoresist pattern 902 includes a photoresist opening 902a wherein an underlying layer will be etched. In alternative embodiments, the photoresist pattern 902 may include patterns to form for example, trenches, gate structures, vias, lines, contacts, source/drain regions, and/or other elements of the peripheral circuit. The SiON layer 306 may be used as an anti-reflective coating when forming the photoresist pattern 902. Thus, in an embodiment, an additional ARC layer is not deposited on the peripheral region 300a. As illustrated, the photoresist layer 902 may partially overlap one of the features 602a of the array region 300b, but does not fill the space (e.g. S3 as illustrated above in reference to FIGS. 8a and 8b).

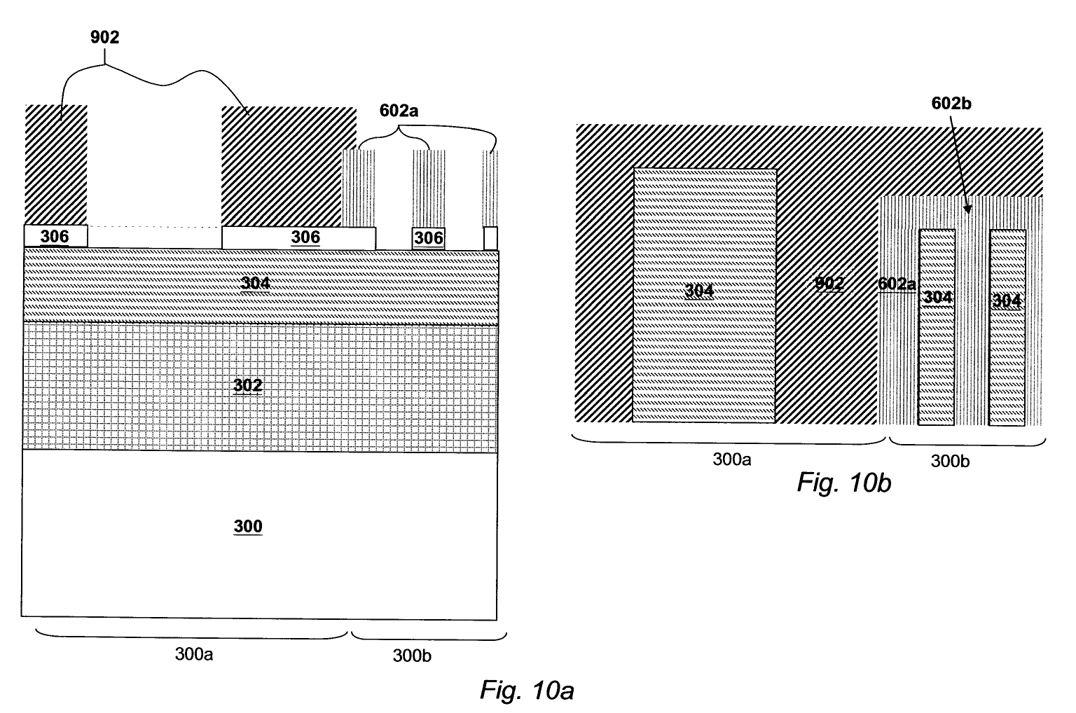

The method 200 proceeds to step 218 where at least one film in the peripheral region and at least one film in the array region are etched concurrently. The etched films may include a dielectric film, a hard mask layer, a SiON layer, an anti-reflective coating, an insulating film, an etch stop layer, and/or other layers known in the art. One or more films may be removed in entirety from the substrate 300. One or more films may be etched such that a pattern is formed. The films may be patterned using the features having a compact pitch, formed above in step 214, as masking elements in the array region, and the photoresist pattern formed above in step 216 as a masking element in the peripheral region. Referring to the example of FIGS. 10a and 10b, the SiON layer 306 is etched using the photoresist pattern 902 and the features 602a at the compact pitch as masking elements. Illustrated in FIGS. 10a and 10b is the array region 300b and the peripheral region 300a of the substrate 300. FIG. 10b includes a top view of the cross-section of FIG. 10a. The SiON layer 306 may be etched concurrently in the peripheral region 300a and the array region 300b. The SiON layer 306 in the array region 300b may be etched to form a pattern having a compact pitch (e.g. P3, described above with reference to FIGS. 8a and 8b). The hard mask layer 304 may be exposed on the removal of the SiON layer 306. The SiON layer 306 may be removed from the peripheral region 300a and the array region 300b by an etch process in a silicon etcher, e.g. a plasma etcher designed for etching silicon.

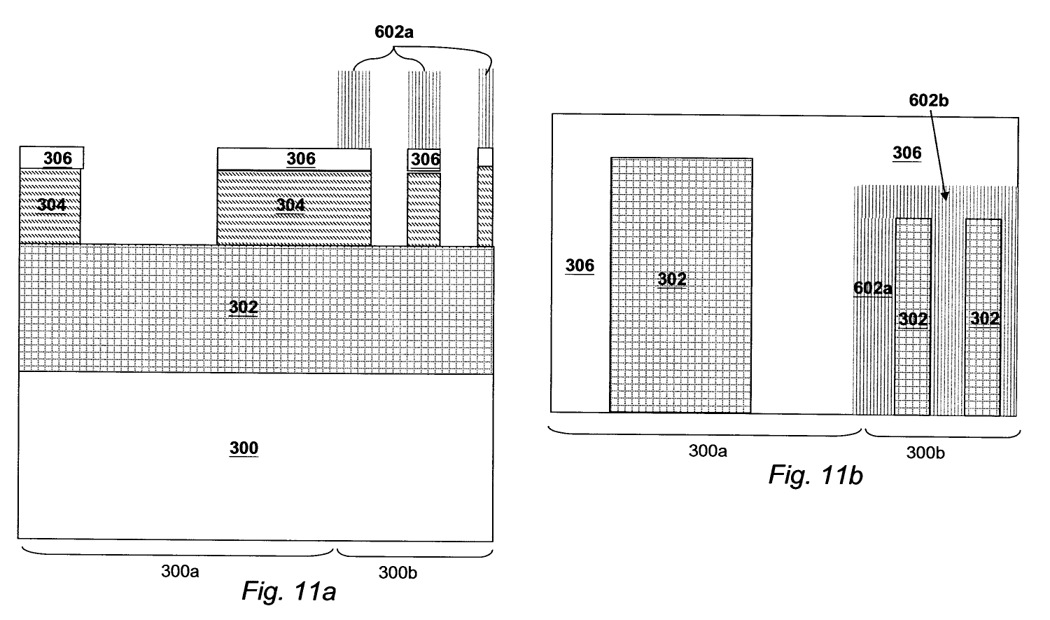

Referring to the example of FIGS. 11a and 11b, the hard mask layer 304 is etched. Illustrated in FIGS. 11a and 11b is the array region 300b and the peripheral region 300a of the substrate 300. FIG. 11b includes a top view of the cross-section of FIG. 11a. The hard mask layer 304 may be etched concurrently in the peripheral region 300a and the array region 300b. The hard mask layer 304 in the array region 300b may be etched to form a pattern having a compact pitch (e.g. P3, described above with reference to FIGS. 8a and 8b). The features 602a may be used as masking elements to etch the hard mask layer 304 in the array region 300b. The remaining SiON layer 306 may used as a masking element to etch the hard mask layer 304 in the peripheral region 300a and/or the array region 300b. The silicon nitride layer 302 may be exposed on the etching to remove the hard mask layer 304. The photoresist pattern 902, illustrated in FIGS. 10a and 10b, may also be removed from the substrate 300. In an embodiment, the photoresist pattern 902 is removed in the same process step (e.g. concurrently) with the hard mask layer 304 as both layers are carbon based materials having similar etch properties.

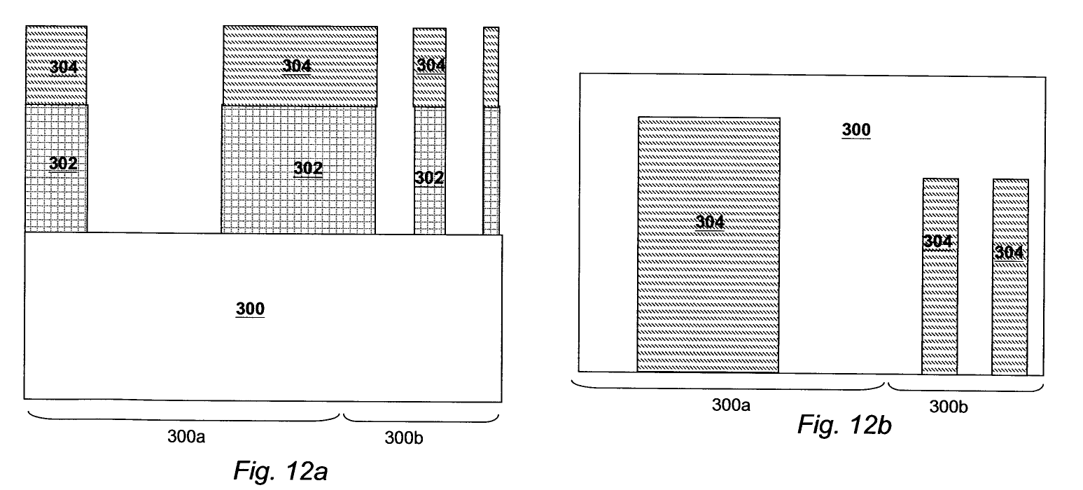

Referring to the example of FIGS. 12a and 12b, the silicon nitride layer 302 is etched using hard mask layer 304 as a masking element. Illustrated in FIGS. 12a and 12b is the array region 300b and the peripheral region 300a of the substrate 300. FIG. 12b includes a top view of the cross-section of FIG. 12a. The silicon nitride layer 302 may be etched concurrently in the peripheral region 300a and the array region 300b. The silicon nitride layer 302 in the array region 300b may be etched to form a pattern having a compact pitch (e.g. P3, described above with reference to FIGS. 8a and 8b). The substrate 300 may be exposed after the etching to remove the silicon nitride layer 302. In an embodiment, the silicon nitride layer 302 may be etched in the peripheral region 300a and the array region 300b in a silicon etcher, e.g. a plasma etcher designed for etching silicon. In addition to etching the silicon nitride layer 302, the etch process may remove the nitride features 602a, including cap 602b of the nitride features, and the SiON layer 306. In an embodiment, the etching and/or removal of the features 602a, cap 602b, SiON layer 306, and the silicon nitride layer 302 are performed in the same process step as all are nitride based materials having similar etch properties. Thus, in the embodiment, the cap 602b is removed without the need for an additional photolithography mask.

One or more of the steps illustrated in FIGS. 10a, 10b, 11a, 11b, 12a, and 12b may be performed in the same chamber and/or concurrently. In an embodiment, one or more of the etches described in FIGS. 10a, 10b, 11a, 11b, 12a, and 12b may be omitted.

The method 200 then proceeds to step 220 where at least one feature is formed concurrently in the array region and the peripheral region of the substrate. The features formed in the array region may include features having a compact pitch (e.g. the pitch defined above in step 214 by the spacers). In an embodiment, the feature formed may include device features including, a trench such as a shallow trench isolation structure, a gate structure, a line such as a metal interconnect line, a via such as to provide contact, and/or other features known in the art. In an embodiment, the feature formed is a pattern etched in a film, such as described above with reference to step 218.

A feature including a gate structure may include the formation of a gate dielectric layer and/or a gate electrode. The gate dielectric layer may include a dielectric material such as, silicon oxide, silicon nitride, silicon oxy-nitride, dielectric with a high dielectric constant (high k), and/or combinations thereof. Examples of high k materials include hafnium oxide, zirconium oxide, aluminum oxide, hafnium dioxide-alumina (HfO₂-Al₂O₃) alloy, or combinations thereof. The gate dielectric layer may be formed using conventional processes such as, photolithography, oxidation, deposition, etching, and/or a variety of other processes known in the art. The gate electrode layer includes conductive material. In an embodiment, the gate electrode includes polysilicon. In other embodiments, the gate may be a metal gate with the gate electrode including a metal composition. Examples of suitable metals for forming the gate electrode include Cu, W, Ti, Ta, TiN, TaN, NiSi, CoSi, and/or combinations thereof. The gate electrode may be formed by conventional processes known in the art such as, physical vapor deposition (PVD) (sputtering), chemical vapor deposition (CVD), plasma-enhanced chemical vapor deposition (PECVD), atmospheric pressure chemical vapor deposition (APCVD), low-pressure CVD (LPCVD), high density plasma CVD (HDPCVD), atomic layer CVD (ALCVD), and/or other processes known in the art including photolithography and etching processes. A feature including a line may include the formation of an interconnect line. The formed interconnect line may comprise copper, aluminum, tungsten, tantalum, titanium, nickel, cobalt, metal silicide, metal nitride, poly silicon, and/or other materials possibly including one or more refractory layers or linings, and may be formed by CVD, PVD, ALD, plating, and/or other conventional processes. A feature including a contact via may include a via etched on the substrate, in particular through one or more layers such as insulating layers formed on the substrate. The via may then be filled with conducting material such as, copper, aluminum, tungsten, tantalum, titanium, nickel, cobalt, metal silicide, metal nitride, polysilicon, and/or other materials possibly including one or more refractory layers or linings. A feature including an STI structure may include a trench that is subsequently filled with an insulating material. The STI structures may be formed by etching apertures in the substrate using conventional processes such as reactive ion etch (RIE). The apertures may then be filled with an insulator material, such as an oxide.

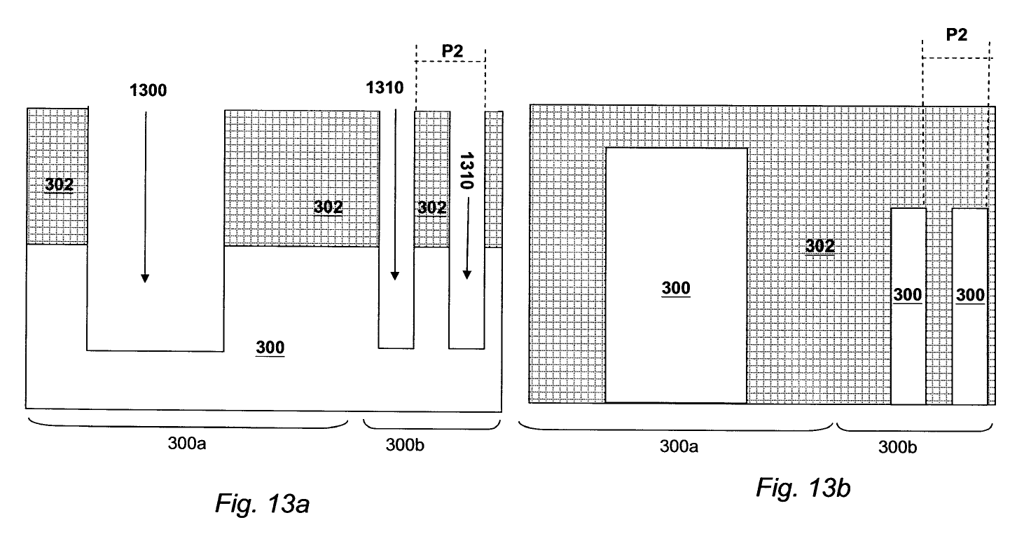

Referring to the example of FIGS. 13a and 13b, a shallow trench isolation (STI) structure 1300 is formed in the peripheral region 300a and a plurality of STI structures 1310 are formed in the array region 300b. The peripheral STI 1300 and the array STI 1310 are formed concurrently. In an embodiment, the peripheral STI 1300 and array STI 1310 are formed in a silicon etcher, e.g. a plasma etcher designed for etching silicon, in the same process (e.g. concurrently). The hard mask layer 304 is also removed (e.g. by an ash process) during the silicon etch. The silicon nitride layer 302, a dielectric, is not etched. In subsequent processes, the STI structures 1300 and/or 1310 may be filled with one or more materials, such as an insulator material (not shown). The pitch of the STI 1310 features is P2, a compact pitch. In an embodiment, P2 is less than the resolution limit of the photolithography tool used in the method 200.

Thus, the method 200 provides for a printing a plurality of features and spaces having a relaxed pitch. Spacers are then formed adjacent the plurality of features to form a compact pitch (such as one-half the relaxed pitch). The method 200 then allows the integrated patterning of the periphery and the array region of the substrate. Based on the patterning, a film underlying the spacers having the compact pitch may be etched in the array region and the peripheral region concurrently. In an embodiment, the method 200 may continue to provide for one or more additional features, such as device features, to be concurrently formed in the array region and the peripheral region.

Thus provided is a method of fabricating a memory device. A substrate including an array region and a peripheral region is provided. A first feature and a second feature are formed in the array region. The first feature and the second feature have a first pitch. A plurality of spacers abutting each of the first feature and the second feature are formed. The plurality of spacers have a second pitch. A third feature in the peripheral region and a fourth and fifth feature in the array region are formed concurrently. The forth and fifth feature have the second pitch.

In another embodiment, a method of fabricating a semiconductor device is provided. A substrate including an array region and a peripheral region is provided. At least one layer on the substrate is formed including on the array region and the peripheral region. A first feature and a second feature is formed on the array region of the substrate. A spacer is formed abutting each of the first feature and the second feature. A pattern is formed in the peripheral region. The at least one layer is etched in the array region using the formed spacer as a masking element. The at least one layer is etched in the peripheral region using the formed pattern as a masking element. The etching the at least one layer in the array region is concurrent with the etching the at least one layer in the peripheral region.

In another embodiment, a method of fabricating a semiconductor device is provided. A substrate including an array region and a peripheral region is provided. A plurality of features are formed in the array region. At least one spacer abutting each of plurality of features are formed. The at least one spacer is used as a mask while concurrently etching the array region and the peripheral region.

What is claimed is:

1. A method of fabricating a memory device, comprising:
providing a substrate including an array region and a peripheral region;
forming a first feature and a second feature in the array region, wherein the first feature and the second feature have a first pitch;
forming a plurality of spacers abutting each of the first feature and the second feature, the plurality of spacers having a second pitch; and
forming a third feature in the peripheral region and a fourth and fifth features in the array region concurrently, wherein the fourth and the fifth feature have the second pitch.

2. The method of claim 1, wherein the second pitch is one-half the first pitch.

3. The method of claim 1, wherein the second pitch is below the resolution limit of a photolithography tool used in the forming the first and the second feature.

4. The method of claim 1, wherein the third feature and the fourth feature and the fifth feature include a feature selected from the group consisting of a trench, an interconnect line, a gate structure, a via, and/or combinations thereof.

5. The method of claim 1, further comprising:
removing the first feature and the second feature from the substrate.

6. The method of claim 1, wherein the third feature comprises a component of a logic circuit.

7. The method of claim 1, wherein the fourth feature and the fifth feature include memory element features of a NAND Flash memory device.

8. A method of fabricating a semiconductor device, comprising:
providing a substrate including an array region and a peripheral region;
forming at least one layer on the substrate including on the array region and the peripheral region;
forming a first feature and a second feature in the array region on the at least one layer;
forming a spacer abutting each of the first feature and the second feature;
forming a pattern in the peripheral region on the least one layer;
etching the at least one layer in the array region using the formed spacer as a masking element; and
etching the at least one layer in the peripheral region using the formed pattern as a masking element, wherein the etching the at least one layer in the array region is concurrent with the etching the at least one layer in the peripheral region.

9. The method of claim 8, further comprising:
trimming the formed first feature and the formed second feature.

10. The method of claim 8, further comprising:
etching the substrate in the array region and etching the substrate in the peripheral region to form a shallow trench isolation structures (STI); wherein the etching the substrate in the array region and the etching the substrate in the peripheral region is concurrent.

11. The method of claim 8, wherein the at least one layer includes silicon oxy-nitride (SiON).

12. The method of claim 8, wherein the at least one layer comprises a material selected from the group consisting of silicon, polysilicon, and oxide.

13. The method of claim 8, wherein the formed spacers include a pitch one-half the pitch of the formed first feature and the formed second feature.

14. The method of claim 8, wherein the formed first feature and second feature have an etch selectivity to the at least one layer of greater than 10 to 1.

15. The method of claim 8, wherein the substrate includes a dielectric layer, a hard mask layer, and an anti-reflective coating layer.

16. The method of claim 15, wherein the dielectric layer is etched in the array region and the peripheral region concurrently, wherein the hard mask layer is etched in the array region and the peripheral region concurrently, and wherein the anti-reflective coating layer is etched in the array region and the peripheral region concurrently.

17. A method of fabricating a semiconductor device, comprising:
providing a substrate including an array region and a peripheral region;
forming a plurality of features in the array region;
forming at least one spacer abutting each of plurality of features; and
using the at least one spacer as a mask while concurrently etching the array region and the peripheral region.

18. The method of claim 17, further comprising
etching the array region and the peripheral region forming a first shallow trench isolation (STI) structure in the array region and concurrently forming a second STI structure in the peripheral region.

19. The method of claim 17, further comprising:
etching the array region and the peripheral region forming a first interconnect in the array region and concurrently forming a second interconnect in the peripheral region.

20. The method of claim 17, further comprising:
etching the array region and the peripheral region forming a first gate structure in the array region and concurrently forming a second gate structure in the peripheral region.
